(19) United States
(12) Patent Application Publication
(10) Pub. No.: US 2005/0189571 A1
(43) Pub. Date: Sep. 1, 2005

(54) Ferroelectric memory

(76) Inventors: Junichi Karasawa, Nagano-Ken (JP); Takamitsu Higuchi, Matsumoto-Shi (JP); Setsuya Iwashita, Nirasaki-Shi (JP)

Correspondence Address: HARNESS, DICKEY & PIERCE, P.L.C., P.O. BOX 828, BLOOMFIELD HILLS, MI, 48303, US

(21) Appl. No.: 11/051,959

(22) Filed: Feb. 4, 2005

(30) Foreign Application Priority Data
Feb. 5, 2004 (JP) 2004-028997

(51) Int. Cl. H01L 29/745

(52) U.S. Cl. 257/213

(57) ABSTRACT

A ferroelectric memory includes a memory cell array in which memory cells having a ferroelectric capacitor are arranged in a matrix shape. The memory cell array includes a ferroelectric layer formed out of a thin film made of a Bi layer-structured ferroelectric single crystal having a (001) orientation and which is patterned such that the ferroelectric layer has two or more side walls perpendicular to a (100) axis of the Bi layer-structured ferroelectrics, first electrodes contacting at least one of the side walls of the ferroelectric layer and which are formed in stripe patterns extending along the one side wall, and second electrodes which contact the other side wall of the ferroelectric layer not contacting the first electrodes and which are formed in stripe patterns to intersect the first electrodes. The memory cells are formed at intersections between the first electrodes and the second electrodes.

### RELATED APPLICATIONS

This application claims priority to Japanese Patent Application No. 2004-028997 filed Feb. 5, 2004 which is hereby expressly incorporated by reference herein in its entirety.

### BACKGROUND

1. Technical Field

The present invention relates to a ferroelectric memory and a method of manufacturing the ferroelectric memory, and more particularly to a simple matrix type ferroelectric memory employing a Bi layer-structured ferroelectric thin film.

2. Related Art

A ferroelectric memory is a memory device having the following features: (1) it is nonvolatile, (2) it executes operation at the same switching speed as a volatile memory, and (3) it executes operation with power consumption lower than other memories.

In a Bi layer-structured ferroelectric (BLSF) thin film, crystals tend to be preferentially oriented in a c-axis ((001) axis) direction due to the anisotropic crystal growth. In the Bi layer-structured ferroelectrics, a polarization axis thereof is parallel to an a-axis ((100) axis) direction perpendicular to the c axis. Accordingly, in a ferroelectric capacitor to which an electric field is applied in the c-axis direction, it is difficult to obtain a hysteresis loop having an excellent angularity. That is, when the Bi layer-structured ferroelectric thin film is used in a parallel plate type ferroelectric capacitor structure obtained by simply stacking electrodes and a ferroelectric layer on a substrate, it is difficult to apply the Bi layer-structured ferroelectric to a simple matrix type (cross-point type) memory enabling highly integration by arranging memory cells in a matrix shape.

The present invention is contrived to solve the above problems, and it is an object of the present invention to provide a ferroelectric memory which can realize a simple matrix memory having excellent characteristics using a Bi layer-structured ferroelectric thin film.

### SUMMARY

The present invention provides a ferroelectric memory having a substrate and a memory cell array in which memory cells having a ferroelectric capacitor are arranged in a matrix shape on the substrate the memory cell array including: a ferroelectric layer which is formed out of a thin film made of a Bi layer-structured ferroelectric single crystalline thin film having a (001) orientation and which is patterned such that the ferroelectric layer has two or more side walls perpendicular to a (100) axis of the Bi layer-structured ferroelectrics; first electrodes which contact at least one of the side walls of the ferroelectric layer and which are formed in stripe patterns extending along the one side wall; and second electrodes which contact the other side wall of the ferroelectric layer not contacting the first electrodes and which are formed in stripe patterns to intersect the first electrodes, wherein the memory cells are arranged at intersections between the first electrodes and the second electrodes. In the present invention, the Bi layer-structured ferroelectrics means a crystal structure having ferroelectricity where a bismuth oxide layer and n pseudo perovskite units are repeated, and an example thereof may include SBT, BLT, BIT, etc.

According to the present invention described above, since the Bi layer-structured ferroelectric single crystalline thin film constituting ferroelectric layers exhibits a (001) orientation, the polarization axis thereof is perpendicular to the (001) axis. At this time, the ferroelectric layer is patterned such that the ferroelectric layer has two or more side walls perpendicular to the (100) axis, and the first electrodes and the second electrodes as electrodes of the ferroelectric capacitors are formed to contact the side walls. Therefore, according to the present invention, by applying an electric field from the first and second electrodes, a polarization characteristic of the Bi layer-structured ferroelectric single crystalline thin film can be pull out to the maximum, so that it is possible to embody a simple matrix type ferroelectric memory comprising memory cells having a capacitor with a hysteresis characteristic excellent in angularity and a high polarization.

In the ferroelectric memory according to the present invention, contact surfaces between the first and second electrodes and the ferroelectric layers may be all perpendicular to the (110) axis of the Bi layer-structured ferroelectrics. According to this structure, since the application direction of the electric field to the ferroelectric layers is perpendicular to the polarization axis of the Bi layer-structured ferroelectrics, the ferroelectric characteristics can be pull out to the maximum.

The present invention also provides a ferroelectric memory comprising a substrate and a memory cell array in which memory cells having a ferroelectric capacitor are arranged in a matrix shape on the substrate the memory cell array including: a ferroelectric layer which is formed out of a thin film made of a Bi layer-structured ferroelectric single crystalline thin film having a (001) orientation and which is patterned such that the ferroelectric layer has two or more side walls perpendicular to a (110) axis of the Bi layer-structured ferroelectrics; first electrodes which contact at least one of the side walls of the ferroelectric layer and which are formed in stripe patterns extending along the one side wall; and second electrodes which contact the other side wall of the ferroelectric layer not contacting the first electrodes and which are formed in stripe patterns to intersect the first electrodes, wherein the memory cells are arranged at intersections between the first electrodes and the second electrodes.

According to the present invention described above, since the Bi layer-structured ferroelectric single crystalline thin film constituting the ferroelectric layers has a (001) orientation, the polarization axis thereof is perpendicular to the (001) axis. At this time, the ferroelectric layer is patterned such that the ferroelectric layer has two or more side walls perpendicular to the (110) axis, and the first electrodes and the second electrodes as electrodes of the ferroelectric capacitors are formed to contact the side walls. Therefore, according to the present invention, by applying an electric field from the first and second electrodes, a so-called 90° domain along the (010) axis can be effectively used as a polarization component as well as a so-called 180° domain along the (100) axis, so that it is possible to embody a simple matrix type ferroelectric memory comprising ferroelectric capacitor memory cells having a hysteresis characteristic excellent in angularity.

In the ferroelectric memory according to the present invention, contact surfaces between the first and second electrodes and the ferroelectric layers may be all perpendicular to the (110) axis of the Bi layer-structured ferroelectrics. According to this structure, since the application direction of the electric field to the ferroelectric layers has a slope of 45° about the polarization axis of the Bi layer-structured ferroelectrics, the 90° domain along the (010) axis can be also effectively used as a polarization component as well as the 180° domain along the (100) axis.

In the ferroelectric memory according to the present invention, a buffer layer made of a perovskite-structured single crystalline oxide whose crystal plane has a (001) orientation may be provided between the substrate and the memory cell array. According to this structure, since it is possible to securely allow the ferroelectric layers to have the (001) orientation, the selection range of a substrate material can be widened.

In the ferroelectric memory according to the present invention, the substrate may be made of a perovskite-structured single crystalline oxide whose crystal plane has a (001) orientation. According to this structure, it is possible to securely allow the ferroelectric layers to have the (001) orientation on the substrate.

In the ferroelectric memory, the single crystalline oxide having a perovskite structure may be one of CaTiO₃, BaTiO₃, and a solid solution thereof.

### BRIEF DESCRIPTION OF THE DRAWINGS

FIG. 1 is a plane view schematically illustrating a first ferroelectric memory.

FIG. 2 is a cross-sectional view schematically illustrating a memory cell array of the first ferroelectric memory.

FIG. 3(A) is a plan view schematically illustrating a step of manufacturing the memory cell array of the first ferroelectric memory and FIG. 3(B) is a cross-sectional view schematically illustrating a step of manufacturing the memory cell array of the first ferroelectric memory.

FIG. 4(A) is a plan view schematically illustrating a step of manufacturing the memory cell array of the first ferroelectric memory and FIG. 4(B) is a cross-sectional view schematically illustrating a step of manufacturing the memory cell array of the first ferroelectric memory.

FIG. 5(A) is a plan view schematically illustrating a step of manufacturing the memory cell array of the first ferroelectric memory and FIG. 5(B) is a cross-sectional view schematically illustrating a step of manufacturing the memory cell array of the first ferroelectric memory.

FIG. 6(A) is a plan view schematically illustrating a step of manufacturing the memory cell array of the first ferroelectric memory and FIG. 6(B) is a cross-sectional view schematically illustrating a step of manufacturing the memory cell array of the first ferroelectric memory.

FIG. 7(A) is a plan view schematically illustrating a step of manufacturing the memory cell array of the first ferroelectric memory and FIG. 7(B) is a cross-sectional view schematically illustrating a step of manufacturing the memory cell array of the first ferroelectric memory.

FIG. 8 is a plan view schematically illustrating a modification of the first ferroelectric memory.

FIG. 9 is a cross-sectional view schematically illustrating a memory cell array according to the modification of the first ferroelectric memory.

FIG. 10 is a cross-sectional view schematically illustrating the memory cell array according to the modification of the first ferroelectric memory.

FIG. 11 is a plane view schematically illustrating a second ferroelectric memory.

FIG. 12 is a cross-sectional view schematically illustrating a memory cell array of the second ferroelectric memory.

FIG. 13 is a plan view schematically illustrating a modification of the second ferroelectric memory.

FIG. 14 is a cross-sectional view schematically illustrating a memory cell array according to the modification of the second ferroelectric memory.

FIG. 15 is a cross-sectional view schematically illustrating the memory cell array according to the modification of the second ferroelectric memory.

### DETAILED DESCRIPTION

Hereinafter, preferred embodiments of the present invention will be described with reference to the drawings.

First Ferroelectric Memory

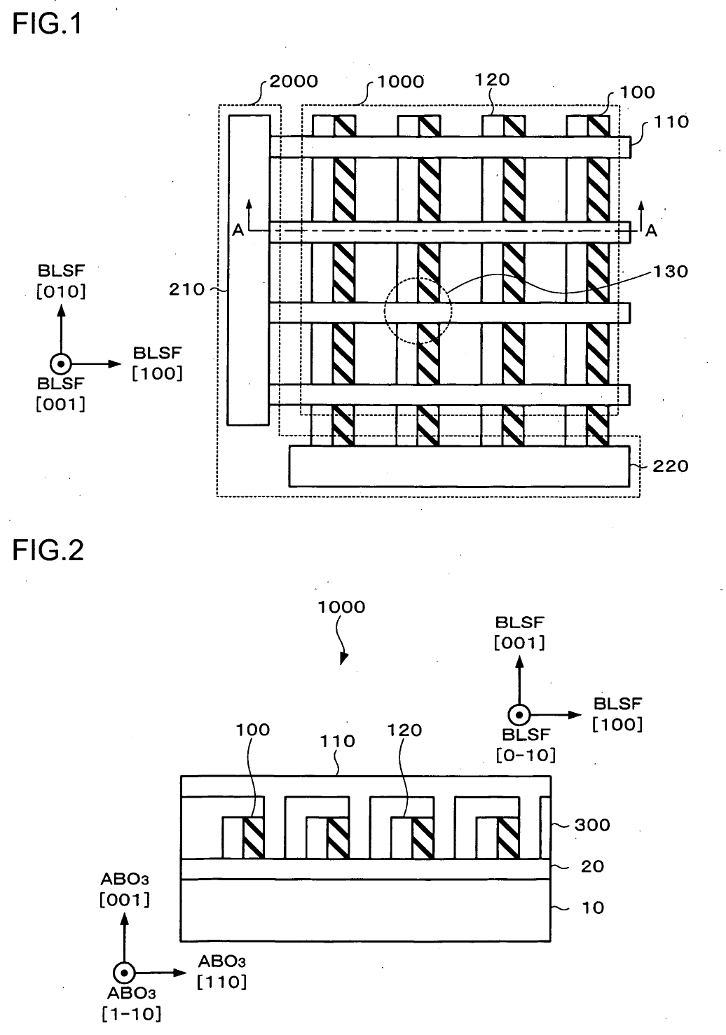

FIG. 1 is a plan view illustrating a first ferroelectric memory according to an embodiment of the present invention. FIG. 2 is a cross-sectional view of a memory cell array 1000 of the first ferroelectric memory taken along Line A-A of FIG. 1.

The first ferroelectric memory is a simple matrix type ferroelectric memory comprising a memory cell array 1000 in which memory cells having a ferroelectric capacitor are arranged in a matrix shape and a peripheral circuit section 2000.

The memory cell array 1000 comprises ferroelectric layers 100, first electrodes 110, and second electrodes 120, which are formed on the substrate 10. The memory cells are formed at intersections 130 between the first electrodes 110 and the second electrodes 120. As shown in the cross-sectional view of FIG. 2, in the memory cell array 1000, an insulating layer 300 made of silicon oxide such as TEOS is provided to isolate the first electrodes and the second electrodes from each other.

As the substrate 10, for example, a semiconductor substrate made of silicon, etc. or an SOI substrate in which an insulating oxide film is formed on a silicon substrate can be used. Further, as the substrate 10, a semiconductor substrate in which peripheral circuits are formed using MOS transistors, etc. may be used.

In the first ferroelectric memory, a buffer layer 20 is interposed between the substrate 10, and the ferroelectric layers 100, first electrodes 110 and second electrodes 120. The buffer layer 20 can be formed such that a single crystalline oxide expressed by ABO₃ and having a perovskite structure of which at least a crystal plane has a (001) orientation is the outermost layer. As a result, the Bi layer-structured ferroelectric single crystalline thin film constituting the ferroelectric layers 100 can be allowed to exhibit the (001) orientation.

An example of the oxide having a perovskite structure expressed by ABO₃ can include CaTiO₃, BaTiO₃, and a solid solution thereof A single crystalline substrate made of the oxide having a perovskite structure expressed by ABO₃ may be used as the substrate 10. In this case, the buffer layer 20 can be omitted.

As needed, the buffer layer 20 may have a multi-layered structure including a plurality of single crystalline layers. In this case, the uppermost layer on which the ferroelectric layer 100 may be formed out of the single crystalline layer which is made of the oxide having the perovskite structure. When the buffer layer 20 has the multi-layered structure, the buffer layer may include single crystalline layers made of the oxide having a NaCl structure and the oxide having a fluorite structure, in addition to the aforementioned layer. In this case, it is enough if at least the uppermost layer of the buffer layer 20 is formed out of the single crystalline layer made of the oxide having the perovskite structure. Since the oxide having the NaCl structure or the oxide having the fluorite structure has an excellent lattice matching property with the oxide having the perovskite structure, it is particularly effective for a case where it is difficult to directly form the oxide having the perovskite structure on the substrate 10.

The oxide having the NaCl structure may include, for example, MgO, CaO, SrO, BaO, MnO, FeO, CoO, NiO, or a solid solution thereof.

The oxide having the fluorite structure may include, for example, YSZ, CeO₂, ZrO₂, ThO₂, UO₂, or a solid solution thereof.

The first electrodes 110 and the second electrodes 120 comprise a plurality of signal electrodes of a line shape functioning as bit lines for selecting columns and word lines for selecting rows, and are formed in stripe patterns to intersect each other. The first electrodes 110 and the second electrodes 120 may be formed such that one thereof functions as the bit lines and the other thereof functions as the word lines. The first electrodes 110 and the second electrodes 120 may be made of, for example, a well-known conductive material such as Pt, II, Ir oxide (IrOₓ), Ru, Ru oxide (RuOₓ), SrRu compound oxide (SrRuOₓ), and the like.

The ferroelectric layer 100 may be made of a Bi layer-structured ferroelectrics having a crystal structure in which a bismuth oxide layer and n pseudo perovskite units are repeated, such as SBT (Strontium Bismuth Tantalate), BIT (Bismuth Titanate), and the like.

In the present embodiment, the ferroelectric layer 100 is made of Bi layer-structured ferroelectric single crystalline thin film having a (001) orientation and has a polarization axis perpendicular to the (001) axis. The ferroelectric layer 100 are patterned to have two side walls (two side walls along the (010) axis) perpendicular to the (100) axis. At the intersections 130 between the first electrodes 110 and the second electrodes 120, the first electrodes 110 and the second electrodes 120 are formed to contact at least the side walls of the ferroelectric layer 100. That is, contact surfaces between the first and second electrodes 110 and 120 and the ferroelectric layer 100 are all perpendicular to the (100) axis of the Bi layer-structured ferroelectrics.

Here, when the number of the pseudo perovskite units disposed between the bismuth oxide layers is even, the Bi layer-structured ferroelectrics has polarization only in an a-axis ((100) axis) direction, and when the number of units is odd, the Bi layer-structured ferroelectrics has polarization in the a-axis direction and a c-axis ((001) axis) direction. However, since the polarization amount in the a-axis direction is sufficiently greater than the polarization amount in the c-axis direction even if the ferroelectrics has polarization in the c-axis direction, it can be said that the Bi layer-structured ferroelectrics basically has the polarization only in the a-axis direction.

Accordingly, in the ferroelectric memory according to the present embodiment, since the polarization axis of the Bi layer-structured ferroelectrics constituting the ferroelectric layer 100 is perpendicular to the direction in which an electric field is applied from the first electrodes 110 and the second electrodes 120, the polarization characteristic of a capacitor can be pulled out to the maximum. Therefore, according to the present embodiment, it is possible to realize a simple matrix type ferroelectric memory having memory cells including a capacitor with high polarization and a hysteresis characteristic excellent in angularity.

In the ferroelectric memory according to the present embodiment, the peripheral circuit section 2000 includes various circuits for writing data to or reading data from the memory cell array 1000, such as a first driving circuit 210 for selectively controlling the first electrodes 110, a second driving circuit 220 for selectively controlling the second electrodes 120, a signal detecting circuit (not shown) such as a sense amplifier, and the like. The peripheral circuit section 2000 may specifically include a Y gate, a sense amplifier, an input and out buffer, an X address decoder, a Y address decoder, an address buffer, and the like.

Next, examples of writing and reading operations in the first ferroelectric memory according to the present embodiment will be described.

First, in the reading operation, a reading voltage is applied to the capacitors of the selected memory cells. This operation combines the writing operation of “0”. At this time, the current flowing through the selected bit lines or the potential when the bit lines are set to high impedance is read out by the sense amplifier. A predetermined voltage is applied to the capacitors of the non-selected memory cells in order to prevent the crosstalk during the reading operation.

In the writing operation, in a case of wring “1”, a writing voltage for inverting a polarized state is applied to the capacitors of the selected memory cells. In a case of writing “0”, the writing voltage for inverting a polarized state is applied to the capacitors of the selected memory cells, so that the state of “0” written during the reading operation is retained. At this time, a predetermined voltage is applied to the capacitors of the non-selected memory cells in order to prevent the crosstalk during the writing operation.

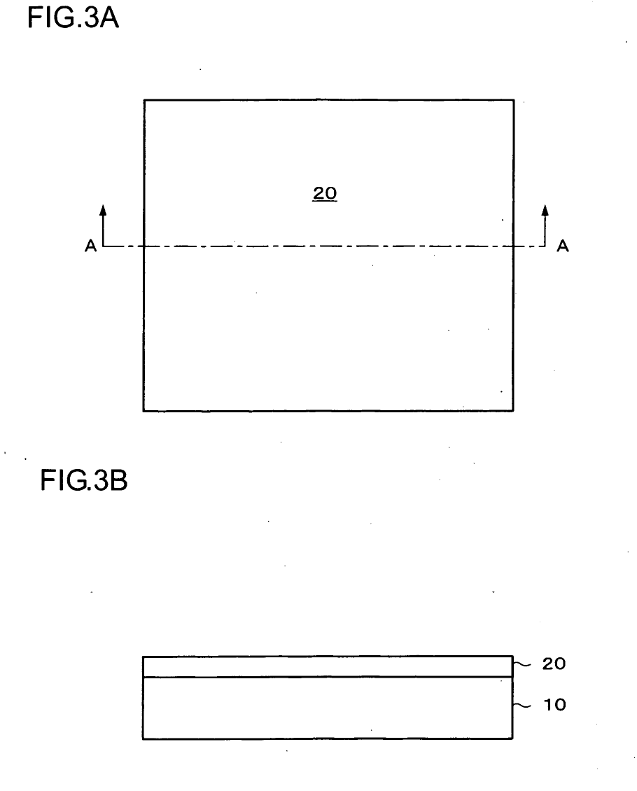

Next, an example of a method of manufacturing the memory cell array 1000 of the first ferroelectric memory according to the present embodiment will be described with reference to FIGS. 3 to 7.

First, as shown in FIGS. 3(A) and 3(B), a predetermined substrate (for example, a silicon substrate) 10 is prepared, and the buffer layer 20 made of the oxide, of which the crystal plane has the (001) orientation and which has the perovskite structure expressed by ABO₃, is formed on the substrate 10 by an epitaxial growth using a ion beam assisting method. When a single crystalline substrate made of the oxide which is suitable for the material of the buffer layer 20 can be prepared as the substrate 10, the above step can be omitted. If the single crystalline layer made of the oxide having the perovskite structure is formed as the uppermost layer, the buffer layer 20 may be formed to have a multi-layered structure. In this case, the buffer layer 20 may include the single crystalline layer made of the oxide having the NaCl structure or the oxide having the fluorite structure.

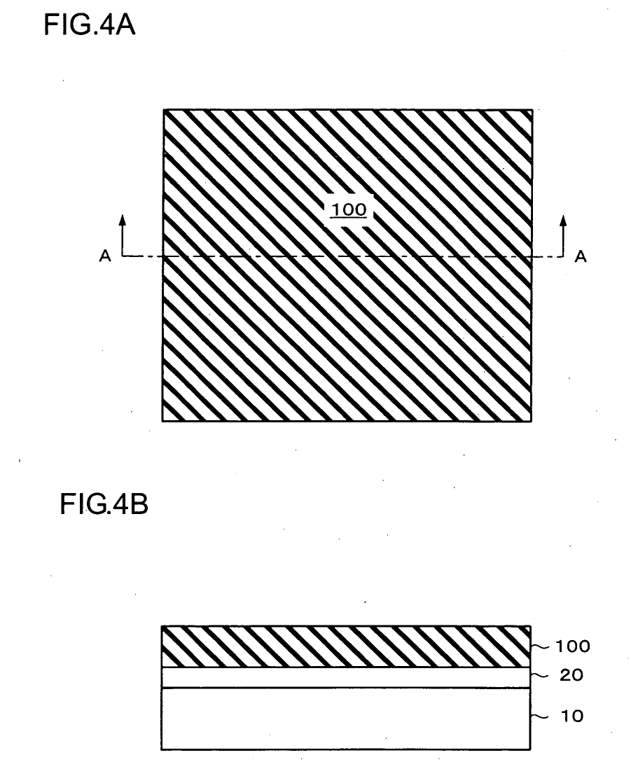

Next, as shown in FIGS. 4(A) and 4(B), the ferroelectric layer 100 made of a Bi layer-structured ferroelectric single crystalline thin film (for example, SBT) is formed on the buffer layer 20 using a solution coating method, a sputtering method, or a CVD (Chemical Vapor Deposition) method. At this time, since perovskite-structured oxide having the (001) orientation exists on the surface of the buffer layer 20, the Bi layer-structured ferroelectrics constituting the ferroelectric layer 100 is formed to have the (001) orientation due to the crystal orientation of the buffer layer 20 as an underlying layer thereof.

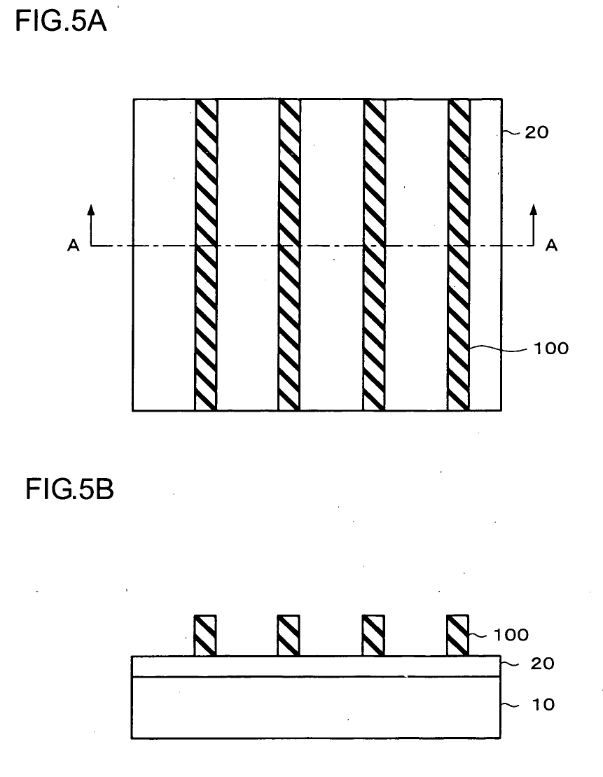

Next, as shown in FIGS. 5(A) and 5(B), the ferroelectric layer 100 is patterned in stripe pattern shapes. At this time, the ferroelectric layer 100 is patterned to have two or more side walls perpendicular to the (100) axis of the Bi layer-structure ferroelectrics. In the present embodiment, the ferroelectric layer 100 is patterned to have two side walls along the (010) axis perpendicular to the (100) axis.

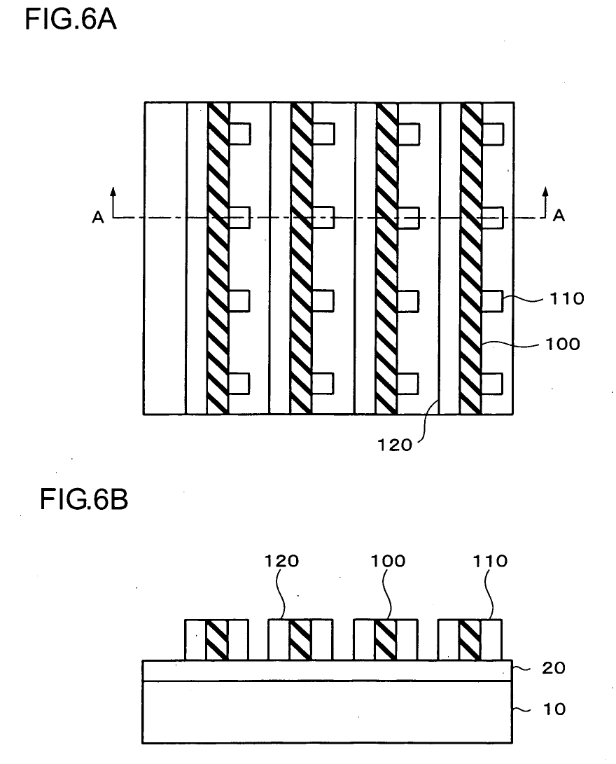

Next, as shown in FIGS. 6(A) and 6(B), the first electrodes 110 and the second electrodes 120 made of, for example, Pt are formed on two side walls of the ferroelectric layer 100, thereby forming the ferroelectric capacitor structure. At this time, the first electrodes 110 are formed to contact one side walls of the ferroelectric layer 100 and are divided in a unit of memory cell. The second electrodes 120 are formed in stripe patterns so as to contact the side walls of the ferroelectric layer 100 other than the side walls contacting the first electrodes.

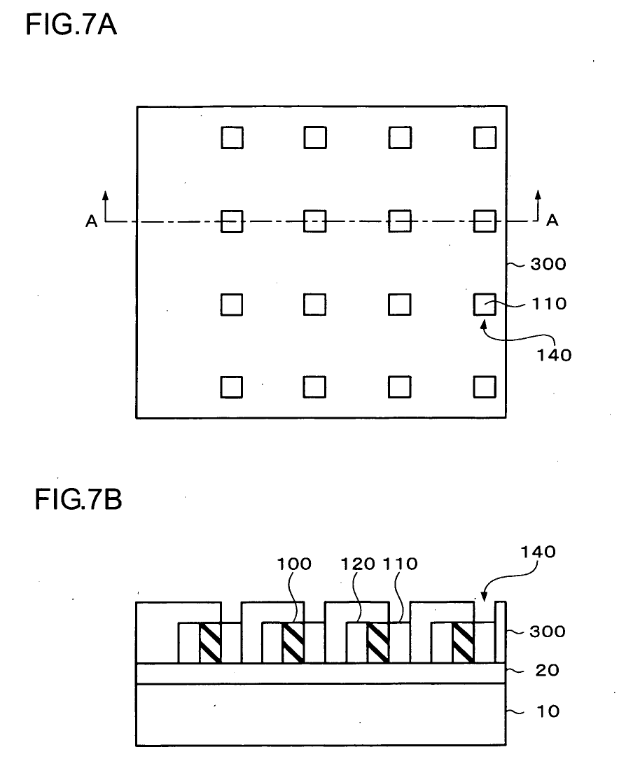

Next, as shown in FIGS. 7(A) and 7(B), the insulating layer 300 is formed to cover the ferroelectric layer 100, the first electrodes 110, and the second electrodes 120, and contact holes 140 are formed in the insulating layer 300 to expose the first electrodes 110. Finally, as shown in FIG. 1, by forming the first electrodes 110 in stripe patterns to interest the second electrodes 120 and electrically connecting the contact holes 140, the memory cell array 1000 of the first simple matrix type ferroelectric memory according to the present embodiment can be obtained.

Modification

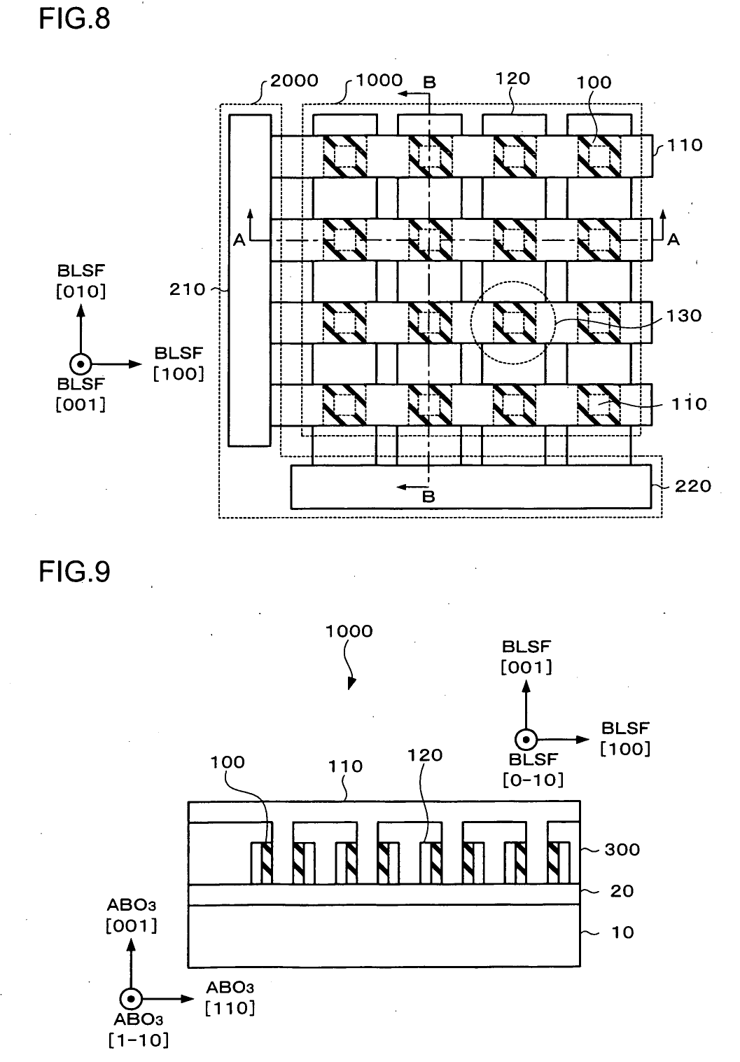

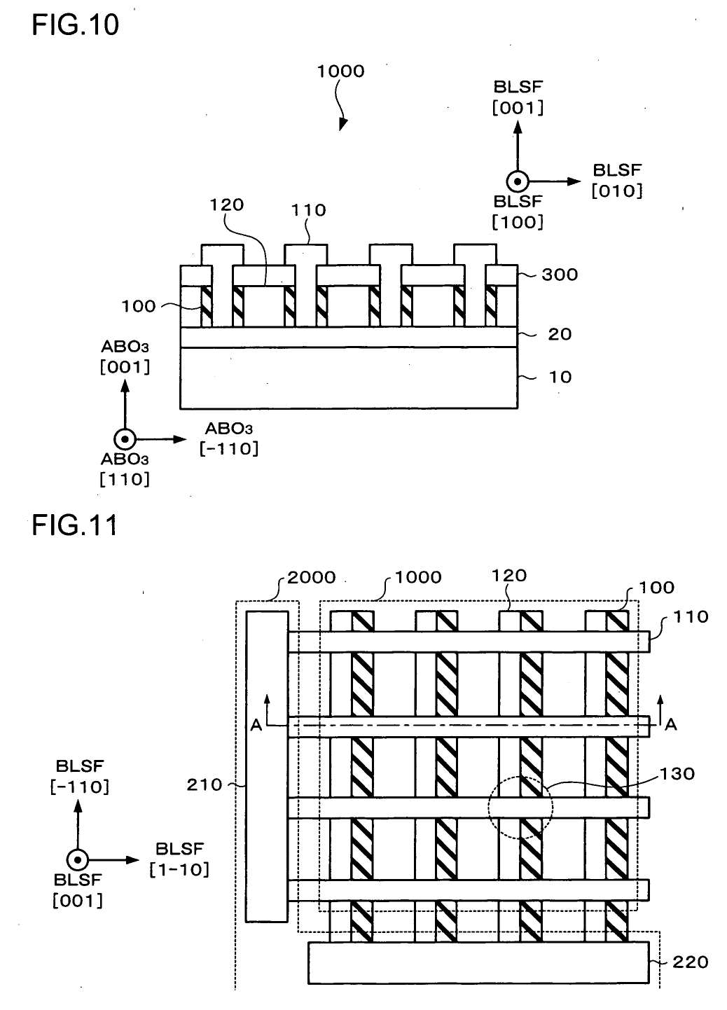

A modification of the first ferroelectric memory according to the present embodiment is shown in FIGS. 8 to 10. FIG. 8 is a plan view of the ferroelectric memory according to the present modification. FIG. 9 is a cross-sectional view of the memory cell array 1000 taken along Line A-A of FIG. 8. FIG. 10 is a cross-sectional view of the memory cell array 1000 taken along Line B-B of FIG. 8. In FIGS. 8 to 10, the elements having substantially the same function as those shown in FIGS. 1 and 2 will be denoted by the same reference numerals and the detailed description thereof will be omitted.

In the ferroelectric memory according to the present modification, the ferroelectric layer 100 is divided and patterned in a unit of memory cells formed at the intersections 130 between the first electrodes 110 and the second electrodes 120. The ferroelectric layer 100 is patterned to have four inner side walls and four outer side walls for each memory cell, such that two of the inner side walls and two of the outer side walls are parallel to the (010) axis perpendicular to the (100) axis of the Bi layer-structured ferroelectrics. The first electrodes 110 contact the outer side walls of the ferroelectric layer 100 and the second electrodes 120 contact the inner side walls of the ferroelectric layer 100. In the present modification, by employing the above structure, it is possible to increase the contact area between the ferroelectric layer 100 and the first and second electrodes 110 and 120 in the respective memory cells, thereby improving characteristics of the memory cell array 1000.

Second Ferroelectric Memory

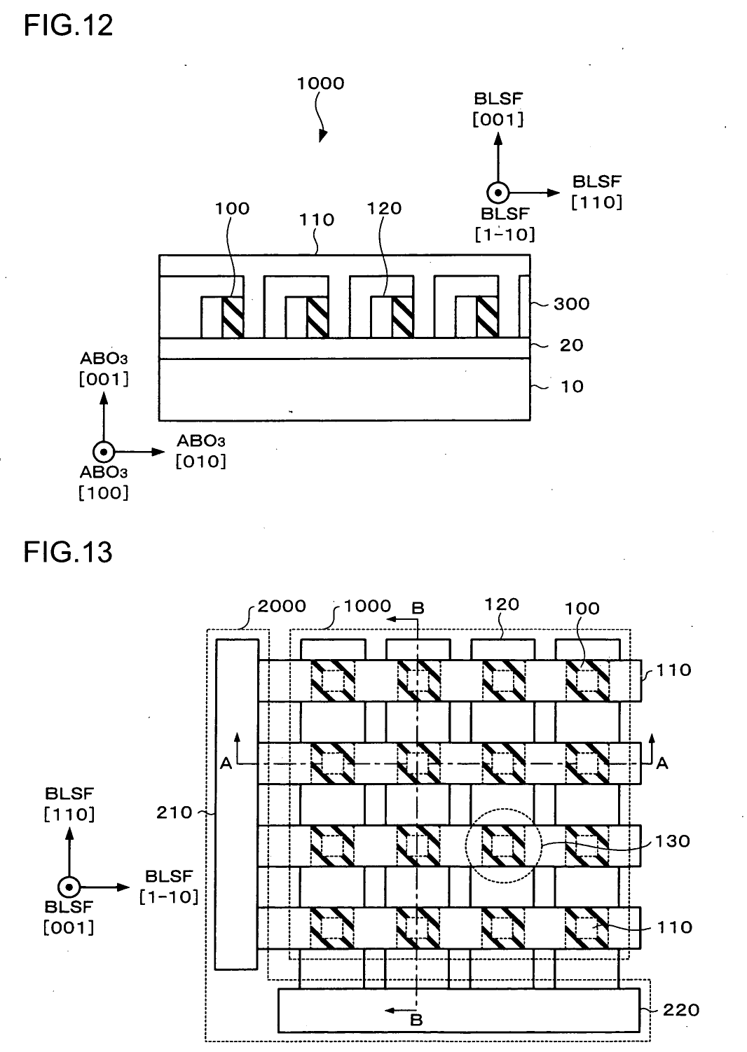

FIG. 11 is a plane view illustrating a second ferroelectric memory according to an embodiment of the present invention. FIG. 12 is a cross-sectional view of the memory cell array 1000 of the second ferroelectric memory taken along Line A-A of FIG. 11. In FIGS. 11 and 12, the elements having substantially the same function as those shown in FIGS. 1 and 2 will be denoted by the same reference numerals and detailed description thereof will be omitted.

The second ferroelectric memory according to the present embodiment has the same basic structure as the first ferroelectric memory shown in FIG. 1, except that the ferroelectric layer 100 is patterned to have two side walls (two side walls parallel to a (−110) axis) perpendicular to the (110) axis of the Bi layer-structured ferroelectrics. In the second ferroelectric memory, the first electrodes 110 and the second electrodes 120 are formed to contact the side walls of the ferroelectric layer 100, and memory cells having a ferroelectric capacitor are formed at the intersections 130 between both electrodes. That is, the contact surfaces between the first and second electrodes 110 and the 120 and the ferroelectric layer 100 are all perpendicular to the (110) axis of the Bi layer-structured ferroelectrics. Therefore, in the second ferroelectric memory according to the present embodiment, since the direction in which an electric field is applied to the ferroelectric layer 100 has a slope of 45° about the polarization axis of the Bi layer-structured ferroelectrics, a so-called 90° domain along the (010) axis can be effectively used as a polarization component as well as a so-called 180° domain along the (100) axis, so that it is possible to embody a simple matrix type ferroelectric memory comprising ferroelectric capacitor memory cells having excellent hysteresis characteristics in angularity.

Modification

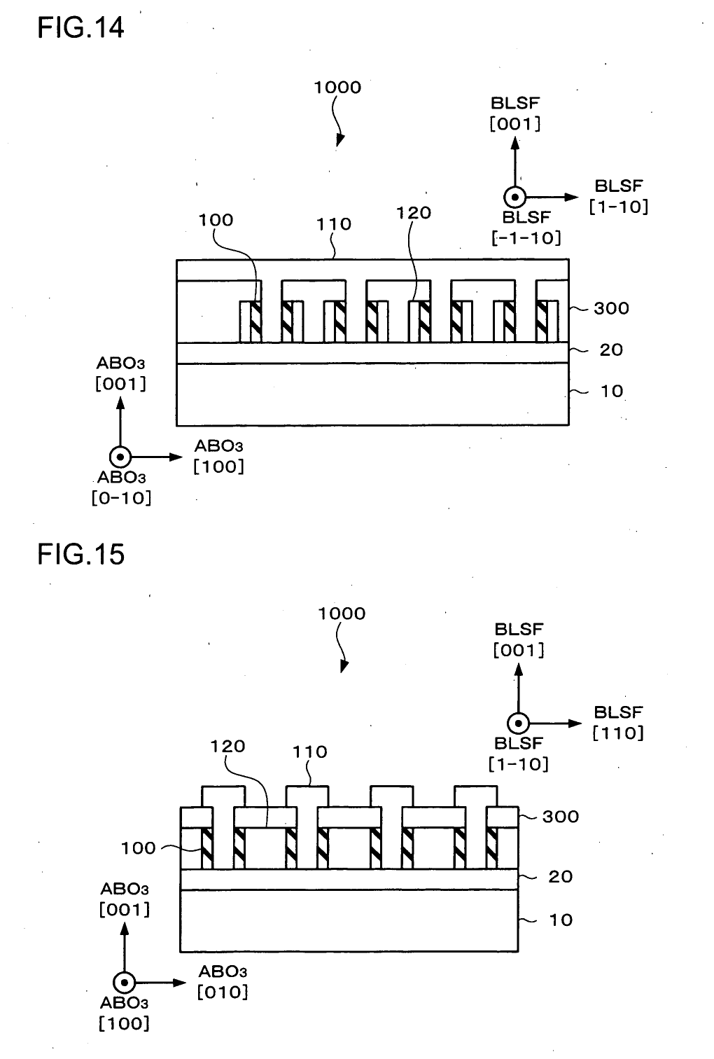

A modification of the second ferroelectric memory according to the present embodiment is shown in FIGS. 13 to 15. FIG. 13 is a plan view of the ferroelectric memory according to the present modification. FIG. 14 is a cross-sectional view of the memory cell array 1000 taken along Line A-A of FIG. 13. FIG. 15 is a cross-sectional view of the memory cell array 1000 taken along Line B-B of FIG. 13. In FIGS. 13 to 15, the elements having substantially the same function as those shown in FIGS. 11 and 12 will be denoted by the same reference numerals and the detailed description thereof will be omitted.

In the ferroelectric memory according to the present modification, the ferroelectric layer 100 is divided and patterned in a unit of memory cells formed at the intersections 130 between the first electrodes 110 and the second electrodes 120. The ferroelectric layer 100 is patterned to have four inner side walls and four outer side walls for each memory cell, such that two of the inner side walls and two of the outer side walls are parallel to the (−110) axis perpendicular to the (110) axis of the Bi layer-structured ferroelectrics. The first electrodes 110 contact the outer side walls of the ferroelectric layer 100 and the second electrodes 120 contact the inner side walls of the ferroelectric layer 100. In the present modification, by employing the above structure, it is possible to increase the contact area between the ferroelectric layer 100 and the first and second electrodes 110 and 120 in the respective memory cells, thereby improving characteristics of the memory cell array 1000.

Although the preferred embodiments of the present invention have been described hitherto, the present invention is not limited to the aforementioned embodiments but may be modified in various forms without departing from the gist of the present invention.

1. A ferroelectric memory having a substrate and a memory cell array in which memory cells having a ferroelectric capacitor are arranged in a matrix shape on the substrate, the memory cell array including:
a ferroelectric layer which is formed out of a thin film made of a Bi layer-structured ferroelectric single crystalline thin film having a (001) orientation and which is patterned such that the ferroelectric layer has two or more side walls perpendicular to a (100) axis of the Bi layer-structured ferroelectrics;
first electrodes which contact at least one of the side walls of the ferroelectric layer and which are formed in stripe patterns extending along the one side wall; and
second electrodes which contact the other side wall of the ferroelectric layer not contacting the first electrodes and which are formed in stripe patterns to intersect the first electrodes,
wherein the memory cells are arranged at intersections between the first electrodes and the second electrodes.

2. The ferroelectric memory according to claim 1,
wherein contact surfaces between the first and second electrodes and the ferroelectric layer are all perpendicular to the (100) axis of the Bi layer-structured ferroelectrics.

3. A ferroelectric memory comprising a substrate and a memory cell array in which memory cells having a ferroelectric capacitor are arranged in a matrix shape on the substrate the memory cell array including:
a ferroelectric layer which is formed out of a thin film made of a Bi layer-structured ferroelectric single crystalline thin film having a (001) orientation and which is patterned such that the ferroelectric layer has two or more side walls perpendicular to a (110) axis of the Bi layer-structured ferroelectrics;
first electrodes which contact at least one of the side walls of the ferroelectric layer and which are formed in stripe patterns extending along the one side wall; and
second electrodes which contact the other side wall of the ferroelectric layer not contacting the first electrodes and which are formed in stripe patterns to intersect the first electrodes,
wherein the memory cells are arranged at intersections between the first electrodes and the second electrodes.

4. The ferroelectric memory according to claim 3
wherein contact surfaces between the first and second electrodes and the ferroelectric layer are all perpendicular to the (110) axis of the Bi layer-structured ferroelectrics.

5. The ferroelectric memory according to claim 3,
wherein a buffer layer made of a perovskite-structured single crystalline oxide whose crystal plane has a (001) orientation is provided between the substrate and the memory cell array.

6. The ferroelectric memory according to claim 3,
wherein the substrate is made of single crystalline oxide whose crystal plane has a (001) orientation and which has a perovskite structure.

7. The ferroelectric memory according to claim 5,
wherein the oxide having the perovskite structure is one of CaTaO₃, BaTiO₃, and a solid solution thereof.

8. The ferroelectric memory according to claim 1,
wherein a buffer layer made of a perovskite-structured single crystalline oxide whose crystal plane has a (001) orientation is provided between the substrate and the memory cell array.

9. The ferroelectric memory according to claim 1,
wherein the substrate is made of single crystalline oxide whose crystal plane has a (001) orientation and which has a perovskite structure.

10. The ferroelectric memory according to claim 8,
wherein the oxide having the perovskite structure is one of CaTaO₃, BaTiO₃, and a solid solution thereof.
